(19) United States
(12) Patent Application Publication
(10) Pub. No.: US 2025/0030389 A1
(43) Pub. Date: Jan. 23, 2025

(54) POWER AMPLIFYING DEVICE

(71) Applicant: Murata Manufacturing Co., Ltd., Kyoto (JP)

(72) Inventor: Kazuhiko ISHIMOTO, Kyoto (JP)

(21) Appl. No.: 18/775,366

(22) Filed: Jul. 17, 2024

(30) Foreign Application Priority Data
Jul. 21, 2023 (JP) 2023-118920

(51) Int. Cl. H03F 3/24; H03F 1/30

(52) U.S. Cl. CPC H03F 3/245; H03F 1/301; H03F 2200/451

(57) ABSTRACT

A bias power supply circuit operates in one of a plurality of current generation modes generating bias power source currents of different levels. The bias power source current is reduced where a first detection signal indicates that a power source voltage is less than a first threshold value. Under control of a bias control circuit, a bias circuit operates in one of an on mode and an off mode wherein the on mode is a mode in which the bias power source current generated by the bias power supply circuit is supplied to a power amplifying transistor as a bias current, and the off mode is a mode in which the bias current whose level is reduced compared with a case where the bias circuit operates in the on mode is supplied or supply of the bias current is stopped.

### CROSS REFERENCE TO RELATED APPLICATION

This application claims priority from Japanese Patent Application No. 2023-118920 filed on Jul. 21, 2023. The content of this application is incorporated herein by reference in its entirety.

### BACKGROUND ART

The present disclosure relates to power amplifying devices.

International Publication No. 2020/080332 (Patent document 1) discloses a power amplifying circuit for radio frequency signals that has protection capability against overcurrent or overvoltage. In the power amplifying circuit disclosed in Patent document 1, the level of a power source current supplied to the collector of a power amplifying transistor is limited in such a manner as to avoid breakdown of a transistor for amplifying power when the overcurrent or overvoltage occurs. Further, when the overcurrent or overvoltage occurs, operation of the power amplifying transistor is stopped by shutting down the current supplied to the base of a biasing transistor that supplies a bias current to the transistor for amplifying power. Because of this, the breakdown of the transistor for amplifying is avoided.

### BRIEF SUMMARY

Because of various internal and external factors and the characteristics of the power amplifying circuit, the restriction of the level of the power source current for preventing the breakdown of the power amplifying transistor or the modification of conditions to stop the operation become suitable. The present disclosure provides a power amplifying device capable of complying with various requests for preventing breakdown of a power amplifying transistor.

According to one aspect of the present disclosure, there is provided a power amplifying device including:
a power amplifying transistor that amplifies power of a radio frequency signal;
a voltage detection circuit that outputs a first detection signal that indicates whether or not a power source voltage applied to the power amplifying transistor is higher than or equal to a first threshold value and a second detection signal that indicates whether or not the power source voltage applied to the power amplifying transistor is higher than or equal to a second threshold value, the second threshold value being higher than the first threshold value;
a bias circuit that supplies a bias current to the power amplifying transistor;
a bias power supply circuit that generates a bias power source current to be supplied to the bias circuit; and
a bias control circuit that controls the bias circuit, wherein
the bias power supply circuit operates in one of a plurality of current generation modes generating the bias power source currents of different levels,
the plurality of current generation modes includes a weak restriction mode in which when the first detection signal indicates that the power source voltage is higher than or equal to the first threshold value, the bias power source current is reduced compared with a case where the first detection signal indicates that the power source voltage is less than the first threshold value,
under control of the bias control circuit, the bias circuit operates in one of an on mode and an off mode, the on mode being a mode in which the bias power source current generated by the bias power supply circuit is supplied to the power amplifying transistor as the bias current, the off mode being a mode in which the bias current whose level is reduced compared with a case where the bias circuit operates in the on mode is supplied or supply of the bias current is stopped, and
when the second detection signal indicates that the power source voltage is higher than or equal to the second threshold value, the bias control circuit is capable of causing the bias circuit to operate in the off mode.

By selecting one mode from the plurality of current generation modes, the level of the bias power source current can be changed. When the level of the bias power source current is reduced, the bias current of the power amplifying transistor decreases, and as a result, the power source current flowing into the collector decreases. By reducing the power source current, it becomes possible to suppress the occurrence of breakdown of the power amplifying transistor. By selecting one mode from the plurality of current generation modes, it becomes possible to comply with various requests to suppress the occurrence of breakdown of the power amplifying transistor in a flexible manner. By causing the bias circuit to operate in the off mode, it becomes possible to stop amplification operation of the power amplifying transistor and suppress the occurrence of breakdown of the power amplifying transistor.

### BRIEF DESCRIPTION OF THE DRAWINGS

FIG. 1 is a block diagram of a power amplifying circuit according to a first working example;

FIG. 2 is an equivalent circuit diagram of a voltage selection circuit;

FIG. 3 is an equivalent circuit diagram of a first voltage current conversion circuit of a bias power supply circuit;

FIG. 4 is a chart illustrating a relationship of a current generation mode to a first detection signal det1 and first mode selection signals p3 and p4;

FIG. 5 is an equivalent circuit diagram of a second voltage current conversion circuit of a bias control circuit;

FIG. 6 is a chart illustrating a relationship of an operation mode of a bias circuit to a second detection signal det2 and second mode selection signals p1 and p2;

FIG. 7 is a graph illustrating a relationship between a power source voltage Vcc and a power source current Icc when the bias power supply circuit operates in a restriction mode with the first mode selection signal p3 being set to a H level and the first mode selection signal p4 being set to a L level, and the bias circuit operates in a strong off mode with the second mode selection signal p1 being set to a H level and the second mode selection signal p2 being set to a L level;

FIG. 8 is a graph illustrating a relationship between the power source voltage Vcc and the power source current Icc when the bias power supply circuit operates in the restriction mode with the first mode selection signal p3 being set to the H level and the first mode selection signal p4 being set to the L level, and the bias circuit operates in a weak off mode with the second mode selection signal p1 being set to the L level and the second mode selection signal p2 being set to the H level;

FIG. 9 is a graph illustrating a relationship between the power source voltage Vcc and the power source current Icc when the bias power supply circuit operates in a non-restriction mode with both the first mode selection signals p3 and p4 being set to the L level, and the bias circuit operates in the strong off mode with the second mode selection signal p1 being set to the H level and the second mode selection signal p2 being set to the L level;

FIG. 10 is a graph illustrating a relationship between the power source voltage Vcc and the power source current Icc when the bias power supply circuit operates in the non-restriction mode with both the first mode selection signals p3 and p4 being set to the L level, and the bias circuit operates in the weak off mode with the second mode selection signal p1 being set to the L level and the second mode selection signal p2 being set to the H level;

FIG. 11 is a graph illustrating a relationship between the power source voltage Vcc and the power source current Icc when the bias power supply circuit operates in a strong restriction mode with the first mode selection signal p3 being set to the L level and the first mode selection signal p4 being set to the H level, and the bias circuit operates in an on mode with both the second mode selection signals p1 and P2 being set to the L level;

FIG. 12 is a graph illustrating a relationship between the power source voltage Vcc and the power source current Icc when the bias power supply circuit operates in the non-restriction mode with both the first mode selection signals p3 and p4 being set to the L level, and the bias circuit operates in the on mode with both the second mode selection signals p1 and p2 being set to the L level;

FIG. 13 is an equivalent circuit diagram of a bias power supply circuit of a power amplifying circuit according to a modified example of the first working example;

FIG. 14 is a block diagram of a power amplifying device according to a second working example;

FIG. 15 is an equivalent circuit diagram of a first voltage current conversion circuit of the power amplifying device according to the second working example;

FIG. 16 is a chart illustrating a relationship of first mode selection signals p3, p4, and p5 to a bias power source current IeC and a current generation mode of a bias power supply circuit in a power amplifying circuit according to the second working example;

FIG. 17 is a graph illustrating a relationship between the power source voltage Vcc and the power source current Icc when the bias power supply circuit operates in a variable restriction mode with both the first mode selection signals p3 and p4 being set to the L level and the first mode selection signal p5 being set to the H level, and the bias circuit operates in the strong off mode (FIG. 6) with the second mode selection signal p1 being set to the H level and the second mode selection signal p2 being set to the L level; and

FIG. 18 is a graph illustrating a relationship between the power source voltage Vcc and the power source current Icc when the bias power supply circuit operates in the variable restriction mode with both the first mode selection signals p3 and p4 being set to the L level and the first mode selection signal p5 being set to the H level, and the bias circuit operates in the weak off mode (FIG. 6) with the second mode selection signal p1 being set to the L level and the second mode selection signal p2 being set to the H level.

### DETAILED DESCRIPTION

### First Working Example

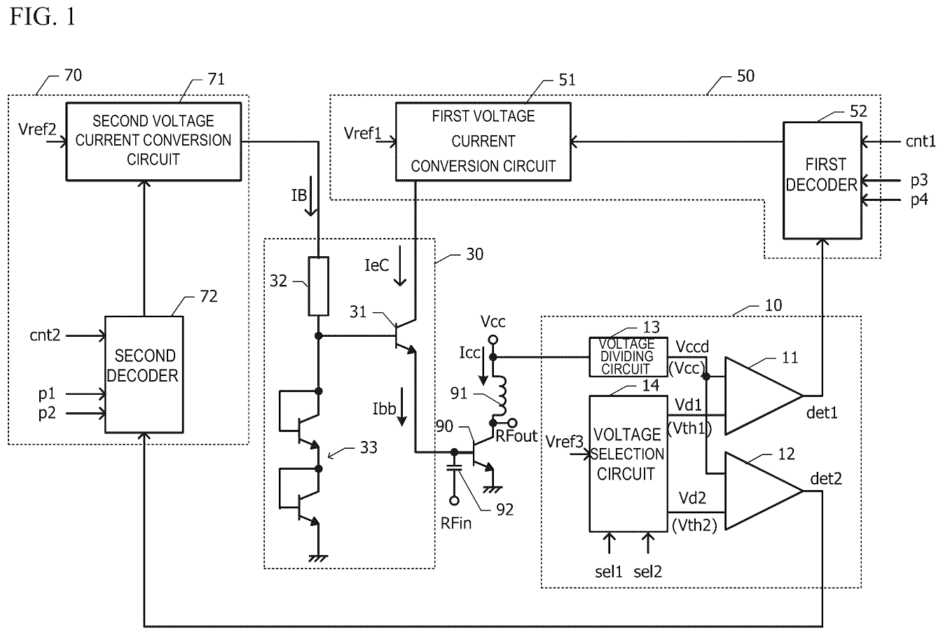

Referring to the drawings from FIG. 1 to FIG. 12, a power amplifying device according to the first working example is described. FIG. 1 is a block diagram of a power amplifying circuit according to the first working example. The power amplifying circuit according to the first working example includes a power amplifying transistor 90, a voltage detection circuit 10, a bias circuit 30, a bias power supply circuit 50, and a bias control circuit 70.

As the power amplifying transistor 90, for example, a heterojunction bipolar transistor is used. A radio frequency signal RFin is input to a base of the power amplifying transistor 90 via a DC-cut capacitor 92. A power source voltage Vcc is applied to a collector of the power amplifying transistor 90 via a choke coil 91. Because of this, a direct-current power source current Icc is supplied to the collector of the power amplifying transistor 90. An amplified radio frequency signal RFout is output from the collector of the power amplifying transistor 90. Note that in the following working examples, field-effect transistors may alternatively be used as transistors including the power amplifying transistor 90. In that case, the configuration of each working example may be understood by replacing the gate with the base, the drain with the collector, and the emitter with the source in each transistor.

Next, the configuration and functions of the voltage detection circuit 10 are described. The voltage detection circuit 10 includes a first comparator 11, a second comparator 12, a voltage dividing circuit 13, and a voltage selection circuit 14. A reference voltage Vref3 and selection signals sel1 and sel2 are input to the voltage selection circuit 14. The voltage selection circuit 14 generates a first voltage Vd1 and a second voltage Vd2 by dividing the reference voltage Vref3 in a manner that depends on the selection signal sel1 and the selection signal sel2, respectively. The second voltage Vd2 is higher than the first voltage Vd1.

The voltage dividing circuit 13 divides the power source voltage Vcc and generates a divided voltage value Vccd. The first comparator 11 compares the divided voltage value Vccd with the first voltage Vd1 and outputs the result of comparison as a first detection signal det1. The second comparator 12 compares the divided voltage value Vccd with the second voltage Vd2 and outputs the result of comparison as a second detection signal det2. The working of the first comparator 11 is virtually equivalent to comparing the power source voltage Vcc (denoted with parenthesis in FIG. 1) before being divided to the divided voltage value Vccd with a first threshold value Vth1 (denoted with parenthesis in FIG. 1) that corresponds to the first voltage Vd1. Furthermore, the working of the second comparator 12 is virtually equivalent to comparing the power source voltage Vcc with a second threshold value Vth2 (denoted with parenthesis in FIG. 1) that corresponds to the second voltage Vd2. The second threshold value Vth2 is higher than the first threshold value Vth1.

That is to say, the voltage detection circuit 10 detects whether or not the power source voltage Vcc is higher than or equal to the first threshold value Vth1, outputs the result of detection as the first detection signal det1, detects whether or not the power source voltage Vcc is higher than or equal to the second threshold value Vth2, and outputs the result of detection as the second detection signal det2. As an example, the first comparator 11 sets the first detection signal det1 to a L level when the power source voltage Vcc is less than the first threshold value Vth1 and sets the first detection signal det1 to a H level when the power source voltage Vcc becomes higher than or equal to the first threshold value Vth1. The second comparator 12 sets the second detection signal det2 to a L level when the power source voltage Vcc is less than the second threshold value Vth2 and sets the second detection signal det2 to a H level when the power source voltage Vcc becomes higher than or equal to the second threshold value Vth2. Note that the first comparator 11 and the second comparator 12 can have hysteresis characteristics.

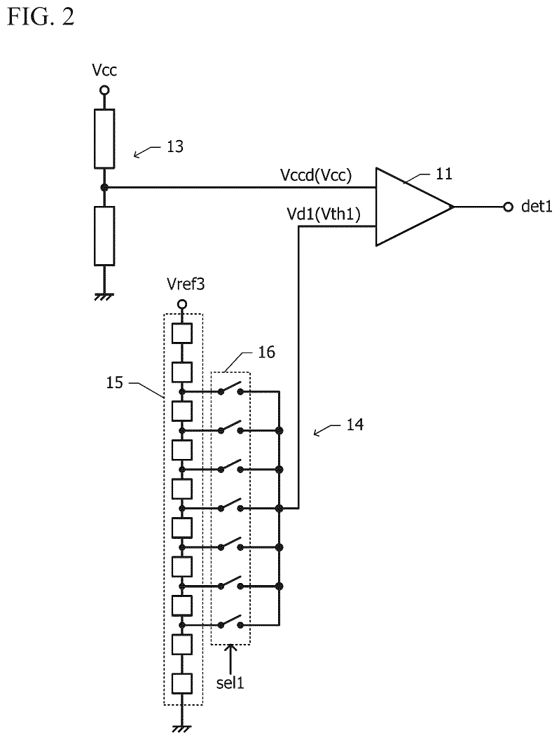

Next, referring to FIG. 2, a detailed configuration of the voltage selection circuit 14 is described. FIG. 2 is an equivalent circuit diagram of the voltage selection circuit 14. The voltage selection circuit 14 includes a multistage voltage dividing circuit 15, in which a plurality of resistive elements is connected in a multistage manner, and a plurality of switches 16, which are respectively connected to a plurality of voltage extraction nodes of the multistage voltage dividing circuit 15. One switch 16 is selected from the plurality of switches 16 by the selection signal sel1 and becomes electrically continuous. Because of this, the voltage (equivalent to the first voltage Vd1) of the voltage extraction node connected to the switch 16 that became electrically continuous is input to one of input nodes of the first comparator 11. The divided voltage value Vccd of the power source voltage Vcc generated by the voltage dividing circuit 13 is input to the other of input nodes of the first comparator 11. A circuit that generates the second voltage Vd2 (FIG. 1) to be input to the second comparator 12 is identical to the circuit that generates the first voltage Vd1, and one of a plurality of switches is selected by the selection signal sel2.

Next, the bias circuit 30 is described. As illustrated in FIG. 1, the bias circuit 30 includes a biasing transistor 31, a resistive element 32, and a diode circuit 33. As the biasing transistor 31, for example, a heterojunction bipolar transistor is used. The diode circuit 33 includes two diode-connected heterojunction bipolar transistors, and these two heterojunction bipolar transistors are connected in series. The bias power source current IeC input from the bias power supply circuit 50 is supplied to the collector of the biasing transistor 31. The emitter current of the biasing transistor 31 is supplied to the base of the power amplifying transistor 90 as a bias current Ibb.

A bias control current IB input from the bias control circuit 70 is supplied to the base of the biasing transistor 31 via the resistive element 32. Part of the bias control current IB flows to ground via the diode circuit 33. The bias control current IB controls a base current (control current) of the biasing transistor 31.

By receiving the bias control current IB from the bias control circuit 70, the bias circuit 30 can operate in one of “on mode” and “off mode”. In the on mode, the bias power source current IeC is supplied to the power amplifying transistor 90 as the bias current Ibb. In the off mode, the bias current Ibb whose level is reduced from the level of the bias current Ibb at a time of the on mode is supplied to the power amplifying transistor 90 or the supply of the bias current Ibb is stopped. Here, the mode in which the bias current Ibb whose level is reduced from the level of the bias current Ibb at a time of the on mode is supplied to the power amplifying transistor 90 is referred to as “weak off mode”, and the mode in which the supply of the bias current Ibb is stopped is referred to as “strong off mode”. In the weak off mode, the level of the bias current Ibb is low, and thus, the power amplifying transistor 90 performs virtually no amplification operation. In other words, in the weak off mode, the power amplifying transistor 90 does not perform amplification operation with a positive gain.

Next, the bias power supply circuit 50 is described. The bias power supply circuit 50 includes a first voltage current conversion circuit 51 and a first decoder 52. The first voltage current conversion circuit 51 generates the bias power source current IeC by converting a reference voltage Vref1 into a current in a manner that depends on a command from the first decoder 52. The generated bias power source current IeC is supplied to the bias circuit 30. On the basis of first mode selection signals p3 and p4, a first control signal cnt1, and the first detection signal det1, the first decoder 52 sends the command to the first voltage current conversion circuit 51.

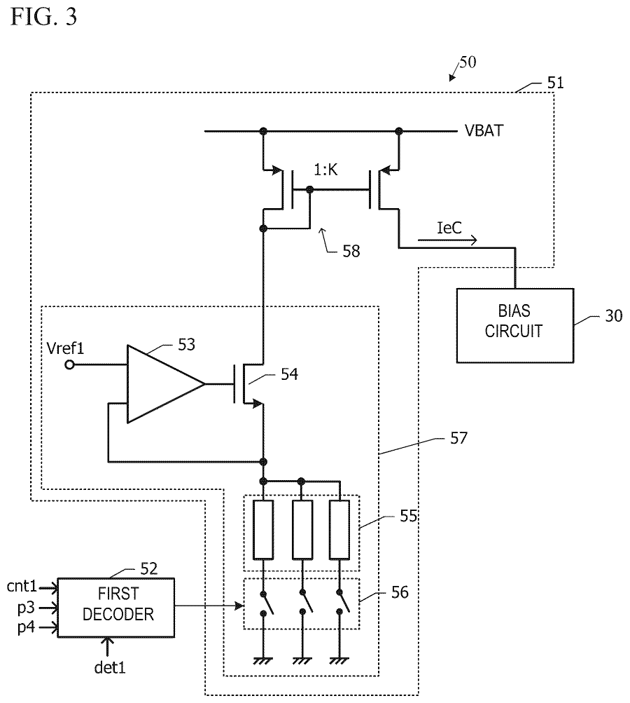

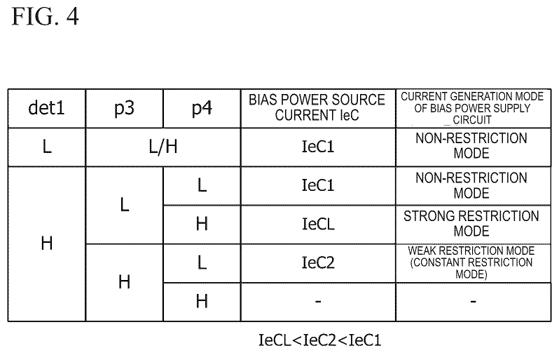

The level of the bias power source current IeC changes in a manner that depends on the first detection signal det1 from the voltage detection circuit 10, which will be described below. A detailed configuration and operation of the bias power supply circuit 50 will be described below with reference to FIG. 3 and FIG. 4.

Next, the bias control circuit 70 is described. The bias control circuit 70 includes a second voltage current conversion circuit 71 and a second decoder 72. By converting a reference voltage Vref2 into a current in a manner that depends on a command from the second decoder 72, the second voltage current conversion circuit 71 generates the bias control current IB. The generated bias control current IB is supplied to the bias circuit 30. On the basis of the second mode selection signals p1 and p2, a second control signal cnt2, and the second detection signal det2, the second decoder 72 sends the command to the second voltage current conversion circuit 71.

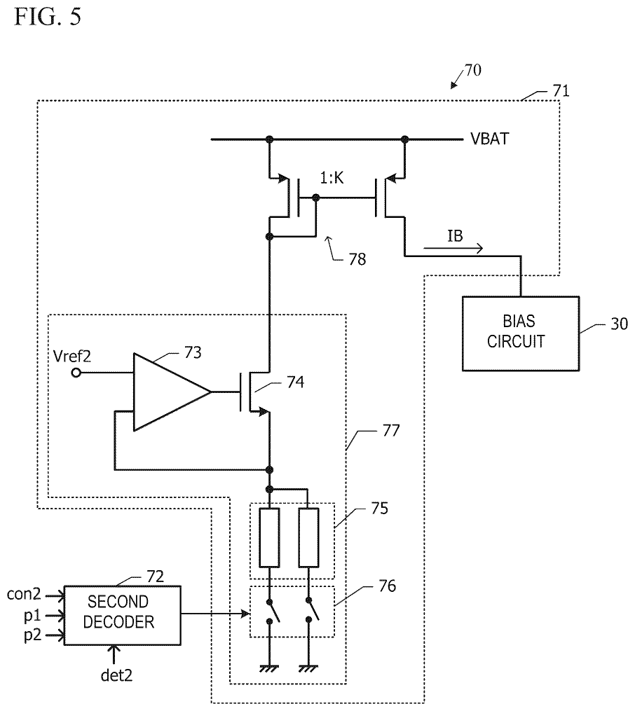

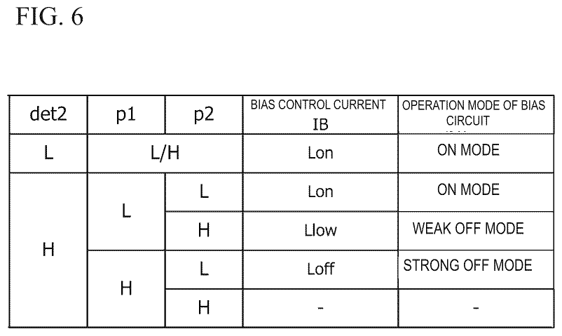

The level of the bias control current IB changes in a manner that depends on the second detection signal det2 from the voltage detection circuit 10, which will be described below. A detailed configuration and operation of the bias control circuit 70 will be described below with reference to FIG. 5 and FIG. 6.

Next, referring to FIG. 3 and FIG. 4, the configuration and operation of the bias power supply circuit 50 are described.

FIG. 3 is an equivalent circuit diagram of the first voltage current conversion circuit 51 of the bias power supply circuit 50. An operational amplifier 53, a n-channel MOSFET 54, three resistive elements 55, and three switches 56 constitute a first constant current source 57. The reference voltage Vref1 is applied to the non-inverting input node of the operational amplifier 53. Resistance values of these three resistive elements 55 are different from each other. Each of the three resistive elements 55 is connected in series to each switch 56. Three series circuit each made up of the resistive element 55 and the switch 56 are connected in parallel to each other. In response to a command from the first decoder 52, the switch 56 is turned on or off. When one switch 56 is selected from the three switches 56 and becomes electrically continuous, the first constant current source 57 generates a current of a constant level that depends on the resistance value of the resistive element 55 connected to the switch 56 that became electrically continuous.

Note that FIG. 3 illustrates the configuration in which the resistance value is switched using the three resistive elements 55 and the three switches 56. However, the way of switching the resistance value is not limited thereto. For example, instead of the configuration that includes as many resistive elements having different resistance values as suitable to realize a required number of the resistance values as illustrated in FIG. 3, the configuration may alternatively be provided with a resistive element group including a plurality of resistive elements having an identical resistance value and a plurality of switches that switches connections among these resistive elements, and the composite resistance value of this resistive element group may be switched.

Two p-channel MOSFETs constitute a first current mirror 58. A battery voltage VBAT is applied to the sources of the two p-channel MOSFETs. The bias power source current IeC is generated by multiplying the drain current of the n-channel MOSFET 54 (current generated by the first constant current source 57) K times using the first current mirror 58 made up of the two p-channel MOSFETs. The bias power source current IeC is supplied to the bias circuit 30.

The first control signal cnt1, the first detection signal det1, and the first mode selection signals p3 and p4 are input to the first decoder 52. The first control signal cnt1 stops the operation of the first voltage current conversion circuit 51 and performs adjustment of the amount of current that is based on the switching of the resistance value of the circuit including the three resistive elements 55.

The bias power supply circuit 50 can operate in any one of a plurality of current generation modes generating the bias power source currents IeC of different levels. For example, in the case where a table such as the one illustrated in FIG. 4, which will be described below, is stored in the first decoder 52, it can be said that the bias power supply circuit 50 can operate in any one of a plurality of current generation modes generating the bias power source currents IeC of different levels. Next, referring to FIG. 4, the relationship of the current generation mode to the first detection signal det1 and the first mode selection signals p3 and p4 is described.

FIG. 4 is a chart illustrating the relationship of the current generation mode to the first detection signal det1 and the first mode selection signals p3 and p4. When the first detection signal det1 is at the L level, that is, the power source voltage Vcc is less than the first threshold value Vth1, the bias power supply circuit 50 sets the level of the bias power source current IeC to IeC1 irrespective of the values of the first mode selection signals p3 and p4.

When the first detection signal det1 is at the H level, that is, the power source voltage Vcc is higher than or equal to the first threshold value Vth1, the bias power supply circuit 50 sets the level of the bias power source current IeC in a manner that depends on the values of the first mode selection signals p3 and p4. When the first mode selection signals p3 and p4 are both at the L level, the level of the bias power source current IeC is set to IeC1. When the bias current Ibb of level IeC1 is supplied to the power amplifying transistor 90 (FIG. 1), the power amplifying transistor 90 performs normal amplification operation. The current generation mode in which the level of the bias power source current IeC is set to IeC1 is referred to “non-restriction mode”.

When the first mode selection signal p3 is at the L level and the first mode selection signal p4 is at the H level, the level of the bias power source current IeC is set to IeCL. The level IeCL is such a low level that even when the bias current Ibb of this level is supplied to the power amplifying transistor 90 (FIG. 1), the power amplifying transistor 90 performs virtually no amplification operation. The current generation mode in which the level of the bias power source current IeC is set to IeCL is referred to “strong restriction mode”.

When the first mode selection signal p3 is at the H level and the first mode selection signal p4 is at the L level, the level of the bias power source current IeC is set to IeC2 that is a constant level lower than IeC1. In this state, compared with the case where the current generation mode is the non-restriction mode, the bias current Ibb supplied to the power amplifying transistor 90 decreases. The power amplifying transistor 90 performs the amplification operation in the state where an operating point has been changed. The current generation mode in which the level of the bias power source current IeC is set to IeC2 is referred to “weak restriction mode”. Further, since the restricted level IeC2 is a constant value, in some cases, this mode is also referred to as “constant restriction mode”.

Next, referring to FIG. 5 and FIG. 6, the configuration and operation of the bias control circuit 70 are described.

FIG. 5 is an equivalent circuit diagram of the second voltage current conversion circuit 71 of the bias control circuit 70. A basic circuit configuration of the second voltage current conversion circuit 71 is identical to the circuit configuration of the first voltage current conversion circuit 51 and includes a second constant current source 77 and a second current mirror 78.

The second constant current source 77 includes an operational amplifier 73, a n-channel MOSFET 74, two resistive elements 75, and two switches 76. The reference voltage Vref2 is applied to the non-inverting input node of the operational amplifier 73. Resistance values of these two resistive elements 75 are different from each other. In response to a command from the second decoder 72, the switch 76 is turned on or off. When one switch 76 is selected from the two switches 76 and becomes electrically continuous, the second constant current source 77 generates a current of a constant level that depends on the resistance value of the resistive element 75 connected to the switch 76 that became electrically continuous.

The bias control current IB is generated by multiplying the drain current of the n-channel MOSFET 74 (current generated by the second constant current source 77) K times using the second current mirror 78. Note that normally, a multiplication factor of current of the second current mirror 78 is different from a multiplication factor of current of the first current mirror 58 (FIG. 3). The bias control current IB is supplied to the bias circuit 30.

The second control signal cnt2, the second detection signal det2, and the second mode selection signals p1 and p2 are input to the second decoder 72. The second control signal cnt2 stops the operation of the second voltage current conversion circuit 71 and adjusts the amount of current. By generating the bias control currents IB of different levels, the bias control circuit 70 switches the operation mode of the bias circuit 30 between the on mode and the off mode. Next, referring to FIG. 6, the relationship of the operation mode of the bias circuit 30 to the second detection signal det2 and the second mode selection signals p1 and p2 is described.

FIG. 6 is a chart illustrating the relationship of the operation mode of the bias circuit 30 to the second detection signal det2 and the second mode selection signals p1 and p2. For example, in the case where a table such as the one illustrated in FIG. 6 is stored in the second decoder 72, it can be said that the bias circuit 30 can operate in any one of a plurality of operation modes, or the bias control circuit 70 can cause the bias circuit 30 to operate in any one of the plurality of operation modes. When the second detection signal det2 is at the L level, that is, the power source voltage Vcc is less than the second threshold value Vth2, the bias control circuit 70 sets the level of the bias control current IB to a normal level Lon irrespective of the values of the second mode selection signals p1 and p2.

When the second detection signal det2 is at the H level, that is, the power source voltage Vcc is higher than or equal to the second threshold value Vth2, the bias control circuit 70 sets the level of the bias control current IB in a manner that depends on the values of the second mode selection signals p1 and p2.

When the second mode selection signals p1 and p2 are both at the L level, the level of the bias control current IB is set to the normal level Lon. When the bias control current IB of the normal level Lon is supplied to the bias circuit 30 (FIG. 1), the level of the bias current Ibb supplied to the power amplifying transistor 90 becomes nearly equal to the level of the bias power source current IeC. The operation mode of the bias circuit 30 at a time when the level of the bias control current IB is set to the normal level Lon is referred to the “on mode”.

When the second mode selection signal p1 is at the L level and the second mode selection signal p2 is at the H level, the level of the bias control current IB is set to a low level Llow. When the bias control current IB of the low level Llow is supplied to the bias circuit 30 (FIG. 1), the bias current Ibb supplied to the power amplifying transistor 90 becomes smaller than the bias current Ibb at a time of the on mode. In this state, the power amplifying transistor 90 performs virtually no amplification operation. The operation mode of the bias circuit 30 at a time when the level of the bias control current IB is set to the low level Llow is referred to the “weak off mode”.

When the second mode selection signal p1 is at the H level and the second mode selection signal p2 is at the L level, the level of the bias control current IB is set to an off level Loff. Specifically, the supply of the bias control current IB is stopped. At this time, the bias current Ibb is not supplied to the power amplifying transistor 90, and the amplification operation of the power amplifying transistor 90 stops. The operation mode of the bias circuit 30 at a time when the level of the bias control current IB is set to the off level Loff is referred to the “strong on mode”.

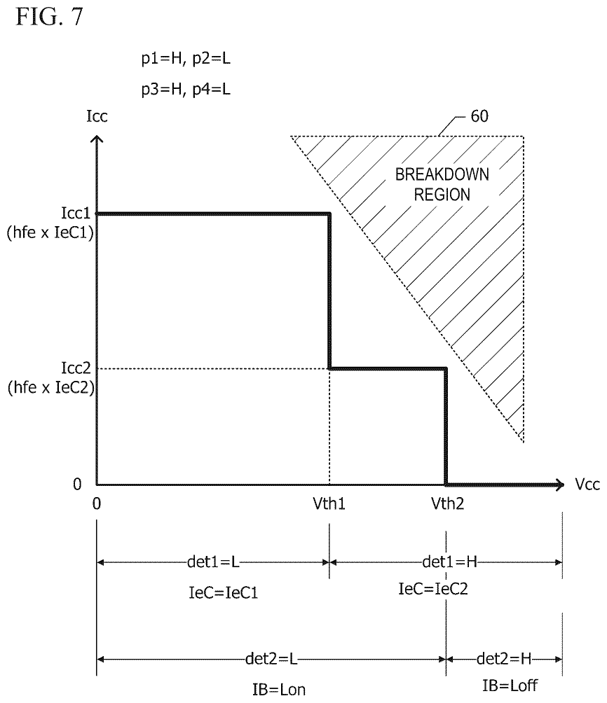

Next, referring to the drawings from FIG. 7 to FIG. 12, the relationship between the power source voltage Vcc and the power source current Icc of the power amplifying transistor 90 is described. The drawings from FIG. 7 to FIG. 12 are graphs illustrating the relationships between the power source voltage Vcc and the power source current Icc of the power amplifying transistor 90. The horizontal axis represents the power source voltage Vcc, and the vertical axis represents the power source current Icc. An approximate breakdown region 60 of the power amplifying transistor 90 is represented by a graphic shaded by hatching.

FIG. 7 is a graph illustrating the relationship between the power source voltage Vcc and the power source current Icc when the bias power supply circuit 50 operates in the restriction mode with the first mode selection signal p3 being set to the H level and the first mode selection signal p4 being set to the L level, and the bias circuit 30 operates in the strong off mode with the second mode selection signal p1 being set to the H level and the second mode selection signal p2 being set to the L level.

When the power source voltage Vcc is less than the first threshold value Vth1 (the first detection signal det1 is at the L level), the level of the bias power source current IeC becomes IeC1, and when the power source voltage Vcc is higher than or equal to the first threshold value Vth1 (the first detection signal det1 is at the H level), the level of the bias power source current IeC becomes IeC2 that is lower than IeC1. When the power source voltage Vcc is less than the second threshold value Vth2 (the second detection signal det2 is at the L level), the level of the bias control current IB becomes the normal level Lon, and the bias circuit 30 (FIG. 1) operates in the on mode.

When the bias circuit 30 operates in the on mode, the power source current Icc is proportional to the bias power source current IeC. Specifically, the level of the power source current Icc becomes nearly equal to the value obtained by multiplying the bias power source current IeC by a current amplification factor hfe of the power amplifying transistor 90. For example, a level Icc1 of the power source current Icc at a time when the level of the bias power source current IeC is IeC1 becomes equal to hfe×IeC1. A level Icc2 of the power source current Icc at a time when the level of the bias power source current IeC is IeC2 becomes equal to hfe×IeC2.

When the power source voltage Vcc becomes higher than or equal to the second threshold value Vth2 (the second detection signal det2 is at the off level Loff), the level of the bias control current IB becomes the off level Loff, and the bias circuit 30 operates in the strong off mode. Because of this, the power source current Icc becomes nearly zero. That is to say, with an increase in the power source voltage Vcc, the power source current Icc decreases in a stepwise manner with two stages.

When an excessive voltage (voltage higher than or equal to the second threshold value Vth2) is applied to the power amplifying transistor 90, the occurrence of breakdown of the power amplifying transistor 90 can be suppressed by stopping the amplification operation of the power amplifying transistor 90. As the power source voltage Vcc increases, the power source current Icc decreases in a stepwise manner with two stages, and thus, it becomes possible to effectively utilize the safe operating region of the power amplifying transistor 90.

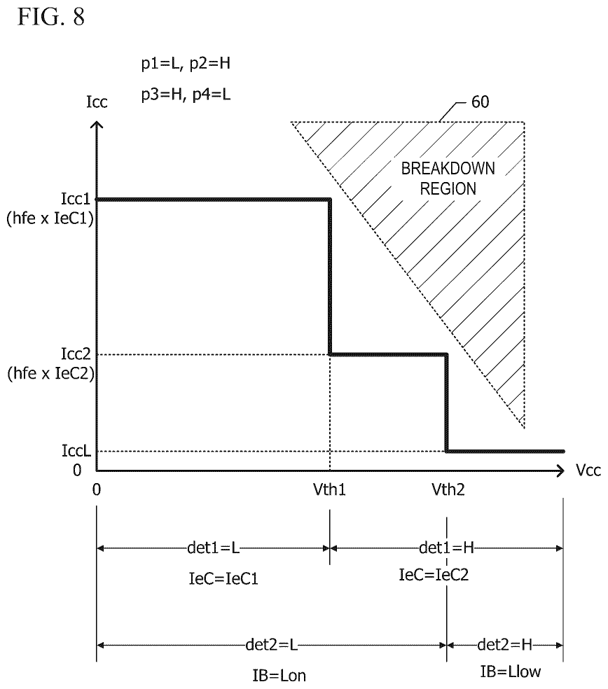

FIG. 8 is a graph illustrating the relationship between the power source voltage Vcc and the power source current Icc when the bias power supply circuit 50 operates in the restriction mode with the first mode selection signal p3 being set to the H level and the first mode selection signal p4 being set to the L level, and the bias circuit 30 operates in the weak off mode with the second mode selection signal p1 being set to the L level and the second mode selection signal p2 being set to the H level.

The relationship between the power source voltage Vcc and the power source current Icc at a time when the power source voltage Vcc is less than the second threshold value Vth2 is identical to the relationship illustrated in FIG. 7. When the power source voltage Vcc becomes higher than or equal to the second threshold value Vth2 (the second detection signal det2 is at the H level), the bias control circuit 70 sets the bias control current IB to the low level Llow. As a result, the operation mode of the bias circuit 30 becomes the weak off mode, and the level of the power source current Icc decreases to IccL. At this level IccL, the power amplifying transistor 90 performs virtually no amplification operation.

Even when the power source voltage Vcc becomes higher than or equal to the second threshold value Vth2, the supply of the bias power source current IeC is not stopped completely (that is to say, the supply of the bias current Ibb is not stopped completely). Thus, compared with the case where the supply of the bias power source current IeC is stopped completely, the recovery time becomes shorter.

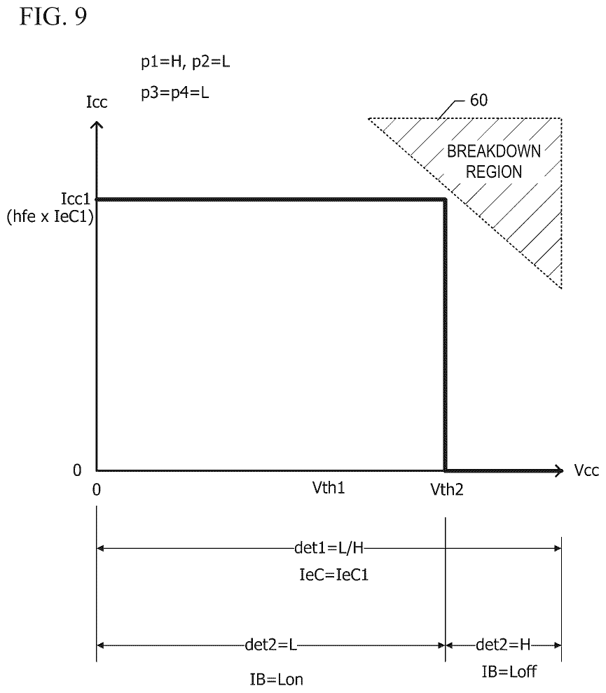

FIG. 9 is a graph illustrating the relationship between the power source voltage Vcc and the power source current Icc when the bias power supply circuit 50 operates in the non-restriction mode with both the first mode selection signals p3 and p4 being set to the L level, and the bias circuit 30 operates in the strong off mode with the second mode selection signal p1 being set to the H level and the second mode selection signal p2 being set to the L level.

Because the bias power supply circuit 50 operates in the non-restriction mode, irrespective of whether or not the power source voltage Vcc is higher than or equal to the first threshold value Vth1, the level of the bias power source current IeC is set to IeC1. When the power source voltage Vcc is less than the second threshold value Vth2 (the second detection signal det2 is at the L level), the bias control current IB is set to the normal level Lon, and thus, the level of the power source current Icc becomes Icc1 (hfe×IeC1).

When the power source voltage Vcc becomes higher than or equal to the second threshold value Vth2 (the second detection signal det2 is at the H level), the bias control current IB is set to the off level Loff. Because of this, as is the case of FIG. 7, the power source current Icc becomes nearly zero. That is to say, when the power source voltage Vcc increases, the power source current Icc decreases in a stepwise manner with a single stage.

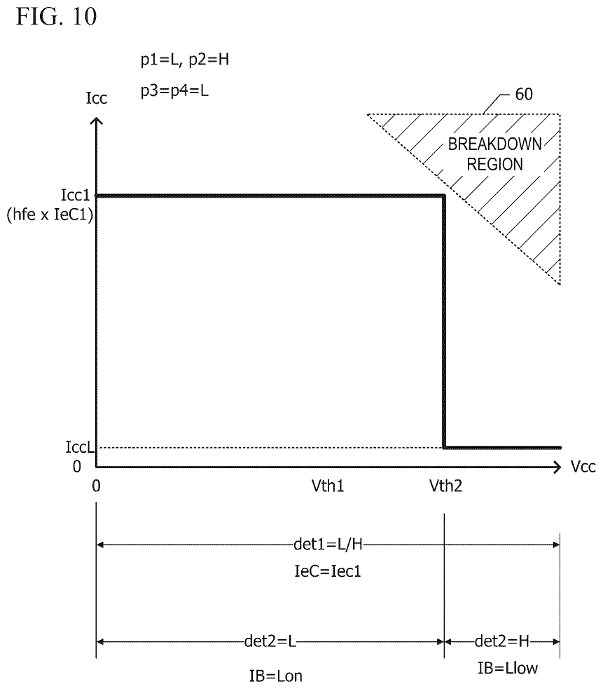

FIG. 10 is a graph illustrating the relationship between the power source voltage Vcc and the power source current Icc when the bias power supply circuit 50 operates in the non-restriction mode with both the first mode selection signals p3 and p4 being set to the L level, and the bias circuit 30 operates in the weak off mode with the second mode selection signal p1 being set to the L level and the second mode selection signal p2 being set to the H level.

The level of the power source current Icc at a time when the power source voltage Vcc is less than the second threshold value Vth2 (the second detection signal det2 is at the L level) is identical to that of the case of FIG. 9. When the power source voltage Vcc becomes higher than or equal to the second threshold value Vth2 (the second detection signal det2 is at the H level), the level of the power source current Icc decreases to IccL, as is the case of FIG. 8. That is to say, when the power source voltage Vcc increases, the power source current Icc decreases in a stepwise manner with a single stage.

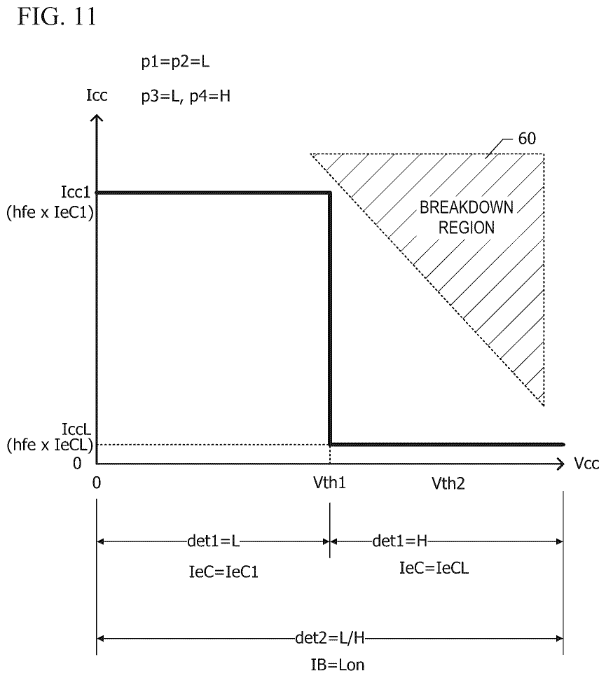

FIG. 11 is a graph illustrating the relationship between the power source voltage Vcc and the power source current Icc when the bias power supply circuit 50 operates in the strong restriction mode with the first mode selection signal p3 being set to the L level and the first mode selection signal p4 being set to the H level, and the bias circuit 30 operates in the on mode with both the second mode selection signals p1 and p2 being set to the L level. The level of the bias control current IB is set to the normal level Lon irrespective of the power source voltage Vcc.

When the power source voltage Vcc is less than the first threshold value Vth1 (the first detection signal det1 is at the L level), by setting the level of the bias power source current IeC to IeC1, the level of the power source current Icc becomes Icc1 (hfe×IeC1). When the power source voltage Vcc becomes higher than or equal to the first threshold value Vth1 (the first detection signal det1 is at the H level), by setting the level of the bias power source current IeC to IeCL, the level of the power source current Icc decreases to IccL (hfe×IeCL). That is to say, when the power source voltage Vcc increases, the power source current Icc decreases in a stepwise manner with a single stage.

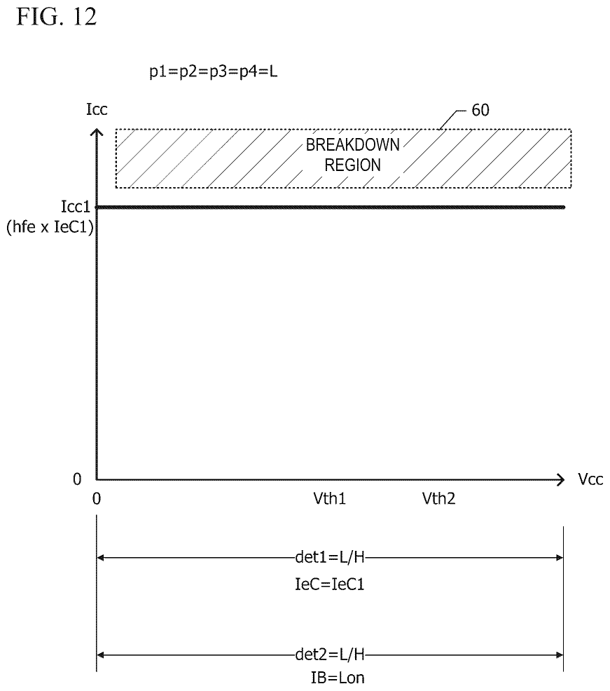

FIG. 12 is a graph illustrating the relationship between the power source voltage Vcc and the power source current Icc when the bias power supply circuit 50 operates in the non-restriction mode with both the first mode selection signals p3 and p4 being set to the L level, and the bias circuit 30 operates in the on mode with both the second mode selection signals p1 and p2 being set to the L level. Irrespective of the power source voltage Vcc, the level of the bias control current IB is set to the normal level Lon, and the level of the bias power source current IeC is set to IeC1.

Because of this, irrespective of the power source voltage Vcc, the level of the power source current Icc becomes a fixed value Icc1 (hfe×IeC1).

Next, effects of the first working example are described. In the first working example, as illustrated in FIG. 4 and FIG. 6, the level of the bias power source current IeC and the operation mode of the bias circuit 30 can be changed using settings of the second mode selection signals p1 and p2 and the first mode selection signals p3 and p4. For example, as illustrated in FIG. 7 and FIG. 8, with the increase in the power source voltage Vcc, the power source current Icc of the power amplifying transistor 90 can be reduced in the stepwise manner with two stages. Furthermore, as illustrated in FIG. 9, FIG. 10, and FIG. 11, the power source current Icc of the power amplifying transistor 90 can be reduced in the stepwise manner with a single stage. In addition, as illustrated in FIG. 12, the power source current Icc of the power amplifying transistor 90 can be maintained nearly constant irrespective of the power source voltage Vcc.

As described above, on the basis of the characteristics of the power amplifying transistor 90, the power source current Icc can be reduced flexibly, and also the amplification operation can be virtually stopped.

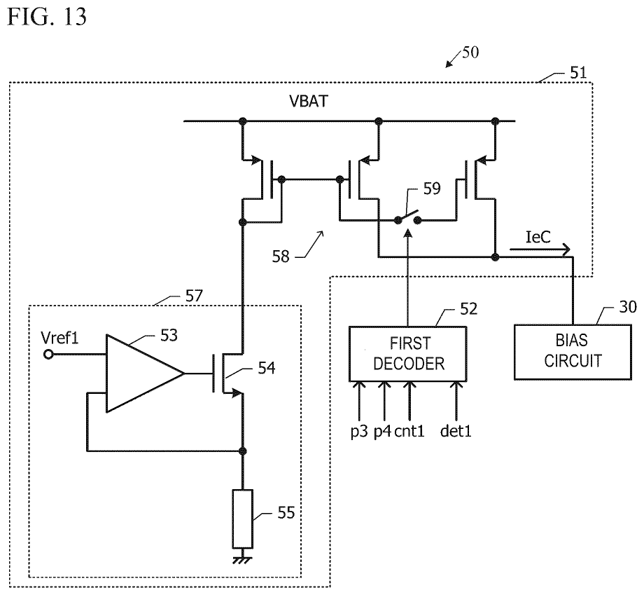

Next, referring to FIG. 13, a bias power supply circuit of a power amplifying circuit according to a modified example of the first working example is described.

FIG. 13 is an equivalent circuit diagram of a bias power supply circuit 50 of the power amplifying circuit according to the modified example of the first working example. In the first working example (FIG. 3), the level of the bias power source current IeC is changed by changing the level of the current generated by the first constant current source 57. In contrast, in the modified example illustrated in FIG. 13, the level of the current generated by the first constant current source 57 is constant. In the present modified example, the level of the bias power source current IeC is changed by changing the multiplication factor of current of the first current mirror 58 in a manner that depends on an output of the first decoder 52.

Specifically, a circuit on the output side of the first current mirror 58 is formed using a parallel circuit made up of a plurality of transistors. The gate of at least one transistor of the plurality of transistors making up the parallel circuit is connected to the gate of a transistor on the input side via a switch 59. The output of the first decoder 52 switches the state of electrical continuity of the switch 59 between being electrically continuous and being electrically discontinuous. By switching the state of electrical continuity of the switch 59 between being electrically continuous and being electrically discontinuous, the multiplication factor of current of the first current mirror 58 can be changed.

With regard to the second voltage current conversion circuit 71 (FIG. 5) of the bias control circuit 70, as is the case with the first voltage current conversion circuit 51 illustrated in FIG. 13, the multiplication factor of current of the second current mirror 78 (FIG. 5) may be set to be variable by setting the resistive elements 75 (FIG. 5) to fixed values without necessarily connecting to the switches 76.

Next, another modified example of the first working example is described. In the first working example, a bipolar transistor is used as the biasing transistor 31. However, a MOSFET may alternatively be used. In this case, the bias power source current IeC is supplied to the drain of the MOSFET. By controlling the gate bias of the MOSFET, the bias control circuit 70 switches between the on mode, the weak off mode, and the strong off mode of the bias circuit 30, which are illustrated in FIG. 6.

### Second Working Example

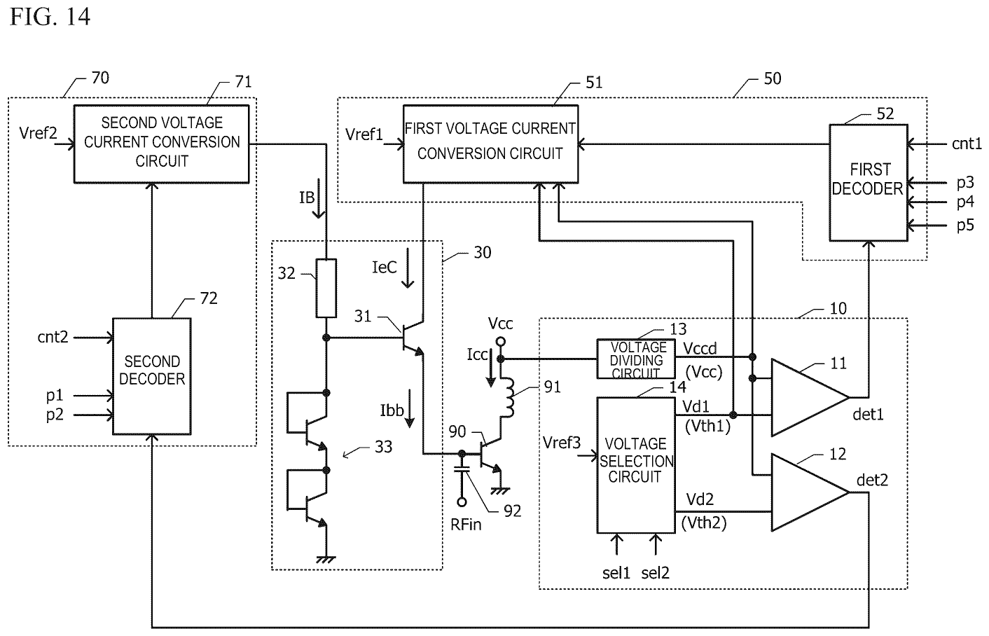

Next, a power amplifying device according to the second working example is described with reference to the drawings from FIG. 14 to FIG. 18. Hereinafter, the descriptions regarding the constituent elements in common with the power amplifying device according to the first working example described with reference to the drawings from FIG. 1 to FIG. 12 are omitted.

FIG. 14 is a block diagram of the power amplifying device according to the second working example. In the first working example (FIG. 1), the output of the first decoder 52 and the reference voltage Vref1 are input to the first voltage current conversion circuit 51. In addition, in the second working example, the divided voltage value Vccd of the power source voltage Vcc generated by the voltage dividing circuit 13 and the first voltage Vd1 generated by the voltage selection circuit 14 are input to the first voltage current conversion circuit 51. Furthermore, in addition to the first mode selection signals p3 and p4, a third first mode selection signal p5 is input to the first decoder 52.

On the basis of the difference between the divided voltage value Vccd of the power source voltage Vcc and the first voltage Vd1 (corresponds to the first threshold value Vth1), the first voltage current conversion circuit 51 changes the level of the bias power source current IeC.

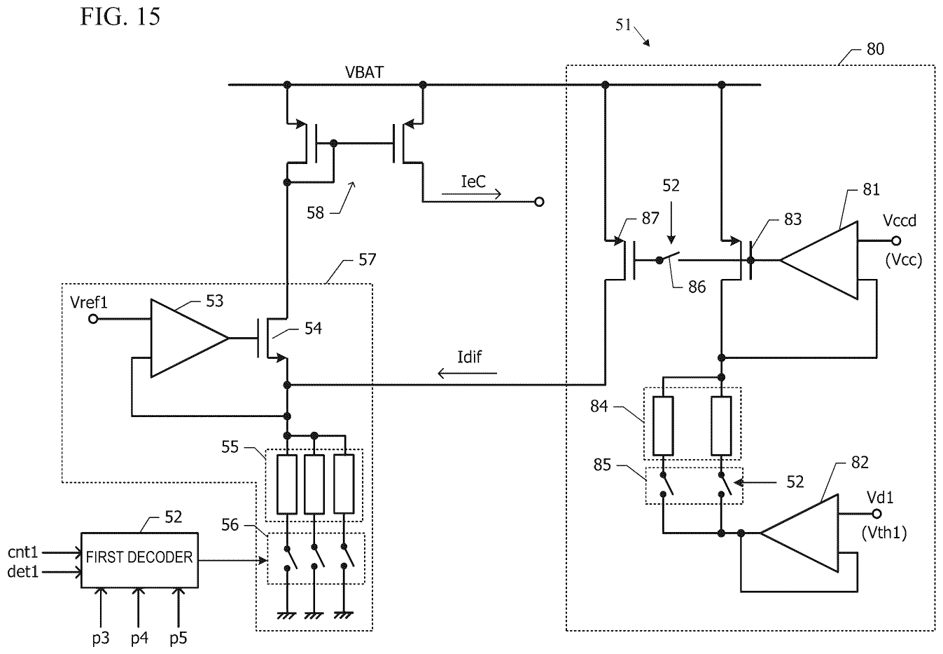

FIG. 15 is an equivalent circuit diagram of the first voltage current conversion circuit 51. The first voltage current conversion circuit 51 of the power amplifying device according to this working example includes, in addition to the first constant current source 57 and the first current mirror 58, a differential current generation circuit 80. The differential current generation circuit 80 generates a differential current Idif whose level depends on the difference between the power source voltage Vcc and the first threshold value Vth1.

Next, the configuration and operation of the differential current generation circuit 80 are described. A third operational amplifier 81, a transistor 83, two resistive elements 84 connected in parallel to each other, switches 85 respectively connected in series to the two resistive elements 84, and a fourth operational amplifier 82 constitute a current source. On and off of the switch 85 is controlled by the output of the first decoder 52.

The voltage that is equivalent to the difference between the divided voltage value Vccd of the power source voltage Vcc and the first voltage Vd1 (corresponds to the first threshold value Vth1) is applied across two end portions of each of the resistive elements 84. The current whose amount is determined by the voltage (hereinafter, referred to as “differential voltage”) that is equivalent to the difference between the divided voltage value Vccd of the power source voltage Vcc and the first voltage Vd1 (corresponds to the first threshold value Vth1) and the resistance values of the resistive elements 84 flows through the transistor 83.

The transistors 83 and 87 constitute a current mirror. When the switch 86 is turned on, this current mirror starts operating, and a current flows into the transistor 87. On and off of the switch 86 is controlled by the output of the first decoder 52. The current flowing through the transistor 87 is output to outside as the differential current Idif. The level of the differential current Idif increases linearly with the differential voltage. Further, the ratio of change in the differential current Idif with respect to the differential voltage decreases as the resistance value of the resistive element 84 increases.

The differential current Idif works in such a manner as to reduce the current generated by the first constant current source 57. Because of this, the level of the bias power source current IeC decreases in a manner that depends on the differential voltage. That is to say, when the differential voltage increases, the amount of decrease in the bias power source current IeC increases.

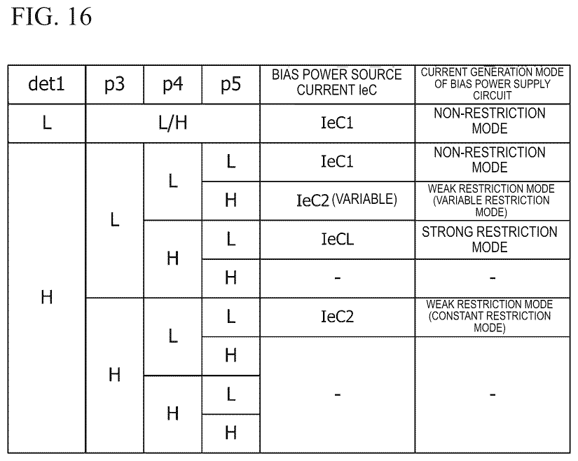

FIG. 16 is a chart illustrating the relationship of the first mode selection signals p3, p4, and p5 to the bias power source current IeC and the current generation mode of the bias power supply circuit 50. When the first mode selection signal p5 is at the L level, the switch 86 becomes electrically discontinuous, and no differential current Idif flows. Because of this, the operation of the bias power supply circuit 50 is identical to that of the case of the first working example (FIG. 4).

In the case where the first mode selection signal p5 is at the H level and both the first mode selection signals p3 and p4 are at the L level, when the first detection signal det1 becomes the H level, the first decoder 52 causes at least one of the switch 85 and the switch 86 to become electrically continuous. Because of this, the level IeC2 of the bias power source current IeC decreases in a manner that depends on the differential voltage. This current generation mode is referred to as the “weak restriction mode”. Further, in some cases, this current generation mode is referred to as “variable restriction mode” to distinguish this current generation mode from the constant restriction mode (FIG. 4).

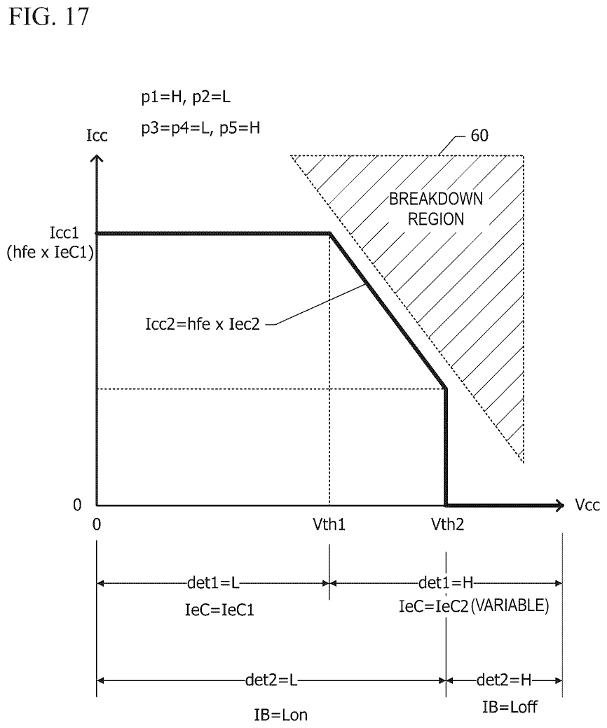

FIG. 17 is a graph illustrating the relationship between the power source voltage Vcc and the power source current Icc when the bias power supply circuit 50 operates in the variable restriction mode with both the first mode selection signals p3 and p4 being set to the L level and the first mode selection signal p5 being set to the H level, and the bias circuit 30 operates in the strong off mode (FIG. 6) with the second mode selection signal p1 being set to the H level and the second mode selection signal p2 being set to the L level.

In the example illustrated in FIG. 7 of the first working example, when the power source voltage Vcc is higher than or equal to the first threshold value Vth1, the level of the bias power source current IeC decreases to IeC2, which is a constant value. In contrast, in the example illustrated in FIG. 17, when the power source voltage Vcc becomes higher than or equal to the first threshold value Vth1 (the first detection signal det1 is at the H level), as the power source voltage Vcc increases, the level IeC2 of the bias power source current IeC gradually continuously decreases. Similarly, the level Icc2 (hfe×IeC2) of the power source current Icc gradually continuously, for example, linearly decreases.

When the power source voltage Vcc increases further and becomes higher than or equal to the second threshold value Vth2 (the second detection signal det2 is at the H level), the level of the bias control current IB becomes the off level Loff, and this stops the supply of the bias power source current IeC. Because of this, the amplification operation of the power amplifying transistor 90 (FIG. 1) stops.

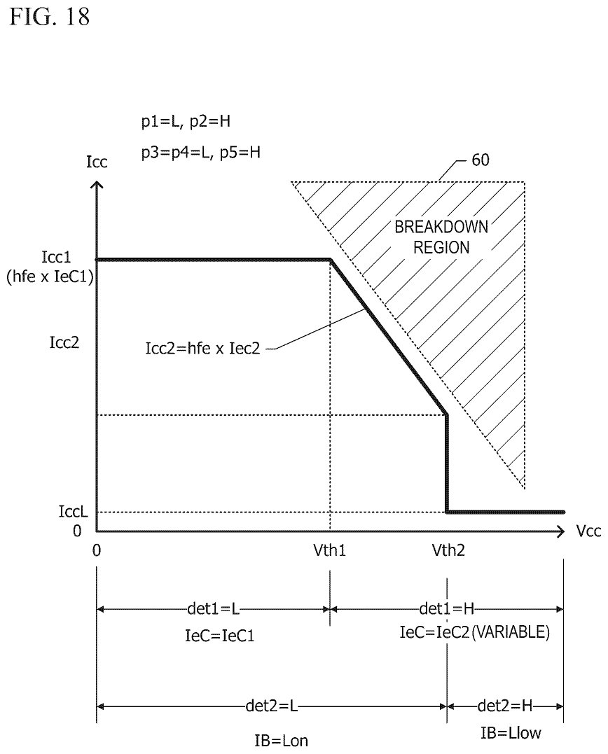

FIG. 18 is a graph illustrating the relationship between the power source voltage Vcc and the power source current Icc when the bias power supply circuit 50 operates in the variable restriction mode with both the first mode selection signals p3 and p4 being set to the L level and the first mode selection signal p5 being set to the H level, and the bias circuit 30 operates in the weak off mode (FIG. 6) with the second mode selection signal p1 being set to the L level and the second mode selection signal p2 being set to the H level.

The relationship between the power source voltage Vcc and the power source current Icc at a time when the power source voltage Vcc is less than the second threshold value Vth2 is identical to that of the case of FIG. 17. When the power source voltage Vcc becomes higher than or equal to the second threshold value Vth2 (the second detection signal det2 is at the H level), the level of the bias control current IB is at the low level Llow, and thus, the level of the bias power source current IeC decreases to IccL.

Next, effects of the second working example are described. As is the case with the first working example, also in the second working example, on the basis of the characteristics of the power amplifying transistor 90, the power source current Icc can be reduced flexibly, and the amplification operation can be virtually stopped. Furthermore, in the second working example, the bias power source current IeC gradually decreases with the increase in the power source voltage Vcc, and thus, it becomes possible to effectively utilize the safe operating region of the power amplifying transistor 90.

Needless to say, each of the foregoing working examples is for illustrative purposes only, and constituent elements illustrated in different working examples may be partially exchanged or combined. Similar functions and effects produced by similar constituting elements of different working examples are not repeated in every working example. Furthermore, the present disclosure is not limited to the foregoing working examples. For example, it would be obvious to a person skilled in the art that various changes, improvements, combinations, or the like can be made.

On the basis of the foregoing working examples described in the present specification, the following disclosure is disclosed.

<1>

A power amplifying device comprising:
a power amplifying transistor that amplifies power of a radio frequency signal;
a voltage detection circuit that outputs a first detection signal that indicates whether or not a power source voltage applied to the power amplifying transistor is higher than or equal to a first threshold value and a second detection signal that indicates whether or not the power source voltage applied to the power amplifying transistor is higher than or equal to a second threshold value, the second threshold value being higher than the first threshold value;
a bias circuit that supplies a bias current to the power amplifying transistor;
a bias power supply circuit that generates a bias power source current to be supplied to the bias circuit; and
a bias control circuit that controls the bias circuit, wherein
the bias power supply circuit operates in one of a plurality of current generation modes generating the bias power source currents of different levels,
the plurality of current generation modes includes a weak restriction mode in which when the first detection signal indicates that the power source voltage is higher than or equal to the first threshold value, the bias power source current is reduced compared with a case where the first detection signal indicates that the power source voltage is less than the first threshold value,
under control of the bias control circuit, the bias circuit operates in one of an on mode and an off mode, the on mode being a mode in which the bias power source current generated by the bias power supply circuit is supplied to the power amplifying transistor as the bias current, the off mode being a mode in which the bias current whose level is reduced compared with a case where the bias circuit operates in the on mode is supplied or supply of the bias current is stopped, and
when the second detection signal indicates that the power source voltage is higher than or equal to the second threshold value, the bias control circuit is capable of causing the bias circuit to operate in the off mode.
   <2>

The power amplifying device according to <1>, wherein
the weak restriction mode includes a constant restriction mode in which the level of the bias power source current is reduced to a constant level, the constant level being lower than the level of the bias power source current at a time when the power source voltage is indicated to be less than the first threshold value.
   <3>

The power amplifying device according to <1> or <2>, wherein
the weak restriction mode includes a variable restriction mode in which as the power source voltage increases, an amount of decrease in the level of the bias power source current with respect to the level of the bias power source current at a time when the power source voltage is indicated to be less than the first threshold value increases.
   <4>

The power amplifying device according to <2>, wherein
the bias power supply circuit includes
   a first decoder that decodes a first mode selection signal that selects the current generation mode and the first detection signal,
   a first constant current source that changes a level of a current to be generated in a manner that depends on an output from the first decoder, and
   a first current mirror that outputs a current generated by the first constant current source as the bias power source current.
      <5>

The power amplifying device according to <2>, wherein
the bias power supply circuit includes
   a first decoder that decodes a first mode selection signal that selects the current generation mode and the first detection signal,
   a first constant current source, and
   a first current mirror that outputs a current generated by the first constant current source as the bias power source current, a multiplication factor of the first current mirror being changed in a manner that depends on an output from the first decoder.
      <6>

The power amplifying device according to <2>, wherein
the bias power supply circuit includes
   a first decoder that decodes a first mode selection signal that selects the current generation mode and the first detection signal,
   a first constant current source, and
   a first current mirror that outputs a current generated by the first constant current source as the bias power source current, a multiplication factor of the first current mirror being changed in a manner that depends on an output from the first decoder.
      <7>

The power amplifying device according to <3>, wherein
the bias power supply circuit includes
   a first decoder that decodes a first mode selection signal that selects the current generation mode and the first detection signal,
   a current source that changes a level of a current to be generated in a manner that depends on an output from the first decoder and a difference between the power source voltage and the first threshold value, and
   a first current mirror that outputs a current generated by the current source as the bias power source current.
      <8>

The power amplifying device according to any one of <1> to <7>, wherein
the plurality of current generation modes further includes a non-restriction mode in which the bias power source current is maintained at a fixed value irrespective of state of the first detection signal.
   <9>

The power amplifying device according to any one of <1> to <8>, wherein
the plurality of current generation modes further includes a strong restriction mode in which when the first detection signal indicates that the power source voltage is higher than or equal to the first threshold value, the level of the bias power source current is reduced to a level at which the power amplifying transistor performs no amplification operation.
   <10>

The power amplifying device according to any one of <1> to <9>, wherein
when the bias control circuit causes the bias circuit to operate in the off mode, the bias control circuit is capable of causing the bias circuit to operate in a strong off mode in which supply of the bias current to the power amplifying transistor is stopped.
   <11>

The power amplifying device according to any one of <1> to <10>, wherein
when the bias control circuit causes the bias circuit to operate in the off mode, the bias control circuit is capable of causing the bias circuit to operate in a weak off mode in which the bias current obtained with the bias power source current of a reduced level is supplied from the bias circuit to the power amplifying transistor.
   <12>

The power amplifying device according to any one of <1> to <11>, wherein
the voltage detection circuit includes
   a first comparator that compares the power source voltage with the first threshold value and outputs a result of comparison as the first detection signal, and
   a second comparator that compares the power source voltage with the second threshold value and outputs a result of comparison as the second detection signal.
      <13>

The power amplifying device according to any one of <1> to <12>, wherein
the bias circuit includes a biasing transistor that supplies the bias current to the power amplifying transistor, and
an emitter or source of the biasing transistor is connected to a base or gate of the power amplifying transistor, the bias power source current is supplied to a collector or drain of the biasing transistor, and a control current of the biasing transistor is controlled by the bias control circuit.
   <14>

The power amplifying device according to any one of <1> to <13>, wherein
the bias control circuit includes
   a second decoder that decodes a second mode selection signal that selects the operation mode of the bias circuit and the second detection signal,
   a second constant current source that changes a level of a current to be generated in a manner that depends on an output from the second decoder, and
   a second current mirror that supplies a current generated by the second constant current source to the bias circuit.
      <15>

The power amplifying device according to any one of <1> to <13>, wherein
the bias control circuit includes
   a second decoder that decodes a second mode selection signal that selects the operation mode of the bias circuit and the second detection signal,
   a second constant current source, and
   a second current mirror that supplies a current generated by the second constant current source to the bias circuit, a multiplication factor of the second current mirror being changed in a manner that depends on an output from the second decoder.

What is claimed is:

1. A power amplifying device comprising:
a power amplifying transistor configured to amplify a power of a radio frequency signal;
a voltage detection circuit configured to output a first detection signal that indicates whether or not a power source voltage applied to the power amplifying transistor is greater than or equal to a first threshold value, and to output a second detection signal that indicates whether or not the power source voltage applied to the power amplifying transistor is greater than or equal to a second threshold value, the second threshold value being larger than the first threshold value;
a bias circuit configured to supply a bias current to the power amplifying transistor;
a bias power supply circuit configured to generate a bias power source current supplied to the bias circuit; and
a bias control circuit configured to control the bias circuit,
wherein the bias power supply circuit is configured to operate in one of a plurality of current generation modes in which the bias power source current is generated at different levels,
wherein the bias power supply circuit is configured to operate in a weak restriction mode as one of the plurality of current generation modes when the first detection signal indicates that the power source voltage is greater than or equal to the first threshold value,
wherein in the weak restriction mode, the bias power supply circuit is configured to generate the bias power source current at a reduced level compared with a case where the first detection signal indicates that the power source voltage is less than the first threshold value,
wherein under control of the bias control circuit, the bias circuit is configured to operate in an on mode or an off mode,
wherein in the on mode, the bias power source current generated by the bias power supply circuit is supplied to the power amplifying transistor as the bias current,
wherein in the off mode, the bias current level is reduced compared with a case where the bias circuit operates in the on mode, or supply of the bias current to the power amplifying transistor is stopped, and
wherein when the second detection signal indicates that the power source voltage is greater than or equal to the second threshold value, the bias control circuit is configured to cause the bias circuit to operate in the off mode.

2. The power amplifying device according to claim 1, wherein the weak restriction mode includes a constant restriction mode in which the level of the bias power source current is reduced to a constant level, the constant level being less than the level of the bias power source current at a time when the power source voltage is less than the first threshold value.

3. The power amplifying device according to claim 1, wherein the weak restriction mode includes a variable restriction mode in which as the power source voltage increases, an amount of decrease in the level of the bias power source current increases with respect to the level of the bias power source current at a time when the power source voltage is less than the first threshold value.

4. The power amplifying device according to claim 2, wherein the bias power supply circuit comprises:
a first decoder configured to decode a first mode selection signal that selects the current generation mode, and to decode the first detection signal,
a first constant current source configured to change a level of a current generated in a manner that depends on an output from the first decoder, and
a first current mirror configured to output a current generated by the first constant current source as the bias power source current.

5. The power amplifying device according to claim 2, wherein the bias power supply circuit comprises:
a first decoder configured to decode a first mode selection signal that selects the current generation mode, and to decode the first detection signal,
a first constant current source, and
a first current mirror configured to output a current generated by the first constant current source as the bias power source current, a multiplication factor of the first current mirror being changed in a manner that depends on an output from the first decoder.

6. The power amplifying device according to claim 3, wherein the bias power supply circuit comprises:
a first decoder configured to decode a first mode selection signal that selects the current generation mode, and to decode the first detection signal,
a current source configured to change a level of a current generated in a manner that depends on an output from the first decoder and a difference between the power source voltage and the first threshold value, and
a first current mirror configured to output a current generated by the current source as the bias power source current.

7. The power amplifying device according to claim 1, wherein the plurality of current generation modes further comprises a non-restriction mode in which the bias power source current is maintained at a fixed value irrespective of state of the first detection signal.

8. The power amplifying device according to claim 1,
wherein the bias power supply circuit is configured to operate in a strong restriction mode as one of the plurality of current generation modes when the first detection signal indicates that the power source voltage is greater than or equal to the first threshold value, and
wherein in the strong restriction mode, the bias power supply circuit is configured to generate the bias power source current at a level at which the power amplifying transistor performs no amplification operation.

9. The power amplifying device according to claim 1, wherein when the bias control circuit causes the bias circuit to operate in the off mode, the bias control circuit is configured to cause the bias circuit to operate in a strong off mode in which supply of the bias current to the power amplifying transistor is stopped.

10. The power amplifying device according to claim 1, wherein when the bias control circuit causes the bias circuit to operate in the off mode, the bias control circuit is configured to cause the bias circuit to operate in a weak off mode in which the bias current obtained with the bias power source current of a reduced level is supplied from the bias circuit to the power amplifying transistor.

11. The power amplifying device according to claim 1, wherein the voltage detection circuit comprises:
a first comparator configured to compare the power source voltage with the first threshold value, and to output a first comparison result as the first detection signal, and
a second comparator configured to compare the power source voltage with the second threshold value, and to output a second comparison result as the second detection signal.

12. The power amplifying device according to claim 1,
wherein the bias circuit comprises a biasing transistor configured to supply the bias current to the power amplifying transistor, and
wherein an emitter or a source of the biasing transistor is connected to a base or a gate of the power amplifying transistor, the bias power source current is supplied to a collector or a drain of the biasing transistor, and a control current of the biasing transistor is controlled by the bias control circuit.

13. The power amplifying device according to claim 1, wherein the bias control circuit comprises:
a second decoder configured to decode a second mode selection signal that selects the operation mode of the bias circuit, and to decode the second detection signal,
a second constant current source configured to change a level of a current generated in a manner that depends on an output from the second decoder, and
a second current mirror configured to supply a current generated by the second constant current source to the bias circuit.

14. The power amplifying device according to claim 1, wherein the bias control circuit comprises:
a second decoder configured to decode a second mode selection signal that selects the operation mode of the bias circuit, and to decode the second detection signal,
a second constant current source, and
a second current mirror configured to supply a current generated by the second constant current source to the bias circuit, a multiplication factor of the second current mirror being changed in a manner that depends on an output from the second decoder.
